(19) United States
(12) Patent Application Publication
(10) Pub. No.: US 2024/0151752 A1
(43) Pub. Date: May 9, 2024

(54) APPARATUS AND METHOD FOR ANALYZING ELECTRICAL LOAD, AND APPARATUS FOR MODELING ELECTRICAL LOAD

(71) Applicant: INSTITUTE FOR INFORMATION INDUSTRY, Taipei (TW)

(72) Inventors: Kuang Ping Tseng, Taipei (TW); Yung Chieh Hung, Taipei (TW); Kuei Chun Chiang, Taipei (TW); Wen Jen Ho, Taipei (TW)

(21) Appl. No.: 17/989,721

(22) Filed: Nov. 18, 2022

(30) Foreign Application Priority Data
Nov. 9, 2022 (TW) 111142783

(51) Int. Cl. G01R 22/06

(52) U.S. Cl. CPC G01R 22/06

(57) ABSTRACT

An apparatus and a method for analyzing an electrical load include: receiving household electricity consumption data and household characteristic data of a user from a client device; selecting an electricity consumption analysis model according to household environment data of the user, and generating an electricity consumption tracking list according to a plurality of feature data of the household electricity consumption data and the household characteristic data via the electricity consumption analysis model; and transmitting the electricity consumption tracking list to the client device. An apparatus for modeling an electrical load includes: receiving a plurality of household electricity consumption data and of household characteristic data from client devices; and generating a plurality of electricity consumption analysis models according to the plurality of household electricity consumption data and the plurality of household characteristic data of the plurality of users.

### TECHNICAL FIELD

The present disclosure relates to a non-invasive load monitoring technology for analyzing an electricity consumption behavior of equipments, in particular to a non-invasive apparatus and method for analyzing an electrical load, and a non-invasive apparatus for modeling the same.

### BACKGROUND

To achieve a goal of energy saving for household users, it is necessary to install hardwares (such as smart sockets, current transformation (CT) meters, or gateways) and softwares (such as data analysis) for intrusive load monitoring (ILM) at home, with higher cost, which makes it unpopular for household users, non-cost-effective, and difficult to widely use.

### SUMMARY

The present disclosure provides a non-invasive load monitoring (NILM) technology for analyzing an electricity consumption behavior of equipments, which may recognize loads of various electrical appliances on the basis of a single electricity meter, without installing electricity monitoring equipment on various electrical appliances, and has advantages of reduced cost and easy use.

An apparatus for analyzing an electrical load provided by the present disclosure includes a receiving module, an analysis module, and a transmission module. The receiving module is configured to receive first household electricity consumption data and first household characteristic data of a first user from a client device; the analysis module is coupled to the receiving module and is configured to select an electricity consumption analysis model of a plurality of electricity consumption analysis models according to first household environment data of the first user and to generate an electricity consumption tracking list according to a plurality of first feature data of the first household electricity consumption data and the first household characteristic data via the electricity consumption analysis model; and the transmission module is coupled to the analysis module and is configured to transmit the electricity consumption tracking list to the client device.

A method for analyzing an electrical load provided by the present disclosure includes: receiving, by a receiving module, first household electricity consumption data and first household characteristic data of a first user from a client device; selecting, by an analysis module, an electricity consumption analysis model of a plurality of electricity consumption analysis models according to first household environment data of the first user, and generating an electricity consumption tracking list according to a plurality of first feature data of the household electricity consumption data and the household characteristic data via the electricity consumption analysis model; and transmitting, by a transmission module, the electricity consumption tracking list to the client device.

An apparatus for modeling an electrical load provided by the present disclosure includes a receiving module and a processing module. The receiving module is configured to receive a plurality of household electricity consumption data and a plurality of household characteristic data of a plurality of users from a plurality of client devices; and the processing module is coupled to the receiving module and is configured to generate a plurality of electricity consumption analysis models according to the plurality of household electricity consumption data and the plurality of household characteristic data of the plurality of users.

The present disclosure collects the household electricity consumption data, the user characteristic data and the household environment data of the user, and provides the data to the electricity consumption analysis models for analyzing electricity consumption histories of various electrical appliances at home. Meanwhile, the present disclosure provides the user with the electricity consumption tracking list of various electrical appliances at home, such that the user can recognize and detect load statuses of various electrical appliances at home and adjust electricity consumption behaviors of various electrical appliances at home according to the load statuses.

### BRIEF DESCRIPTION OF DRAWINGS

FIG. 1 is a schematic diagram of a system for analyzing an electrical load provided by an embodiment of the present disclosure;

FIG. 2 is a schematic diagram of an apparatus for modeling an electrical load provided by an embodiment of the present disclosure;

FIG. 3 is a modeling flowchart of an apparatus for modeling an electrical load provided by an embodiment of the present disclosure;

FIG. 4 is a flowchart of generating a plurality of electricity consumption analysis models provided by an embodiment of the present disclosure;

FIG. 5 is a system block diagram of an apparatus for analyzing an electrical load provided by an embodiment of the present disclosure;

FIG. 6 is a flowchart of a method for analyzing a household electrical load provided by an embodiment of the present disclosure;

FIG. 7 is a flowchart of preprocessing household electricity consumption data to generate feature data provided by an embodiment of the present disclosure; and

FIG. 8 is a modeling flowchart of an apparatus for modeling an electrical load provided by another embodiment of the present disclosure.

### DETAILED DESCRIPTION OF EMBODIMENTS

First, it should be noted that in the embodiment of the present disclosure, the coupling includes a direct electrical connection and an electrical connection through other component, module, or device, that is, an indirect electrical connection. The “coupling” in the description below includes these connections, and will not be repeated in the description below.

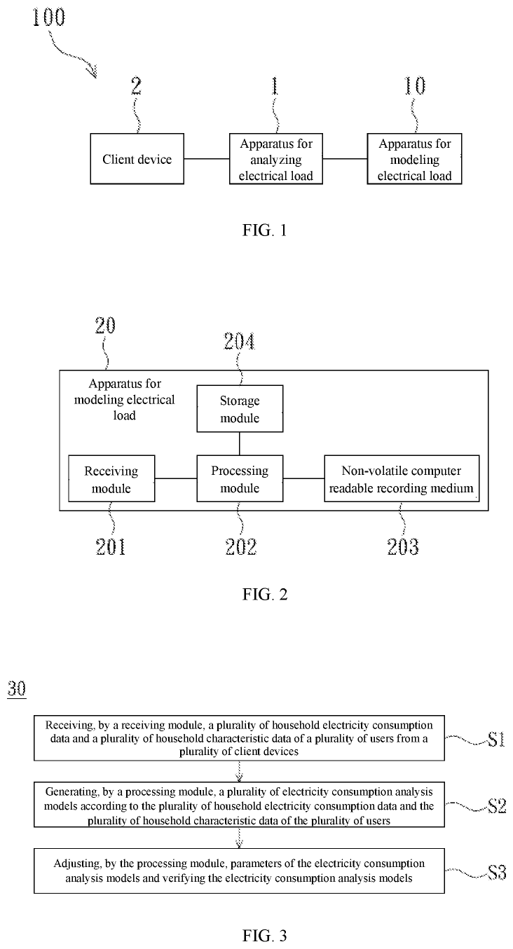

Referring to FIG. 1, it is a schematic diagram of a system 100 for analyzing an electrical load provided by an embodiment of the present disclosure. An apparatus 1 for analyzing an electrical load provided by the present disclosure is connected to a client device 2 and an apparatus 10 for modeling an electrical load, and is configured to generate an electricity consumption tracking list of estimated electricity consumption statuses of various electrical appliances of a user via one of a plurality of electricity consumption analysis models according to household electricity consumption data and household environment data of the user, where the household electricity consumption data is, for example, but not limited to the total circuit electricity consumption, the household environment data is, for example, but not limited to temperature and/or humidity, and various electrical appliances are, for example, but not limited to an air conditioner, a refrigerator, a washing machine, a television, and/or a water dispenser. In addition, in other embodiments, the apparatus 1 for analyzing the electrical load is connected to the client device 2 and the apparatus 10 for modeling the electrical load, and the apparatus 10 for modeling the electrical load may also be connected to the client device 2. When the user needs to obtain electricity consumption histories of various electrical appliances at home, the user may perform registration and subscription by connecting the client device 2 to the apparatus 1 for analyzing the electrical load. An operator of the apparatus 1 for analyzing the electrical load may install an electricity meter and a gateway at home of the user, collect the household electricity consumption data by using the electricity meter, and collect user characteristic data of the user using various electrical appliances at home, where the household electricity consumption data is, for example, but not limited to the total circuit electricity consumption, and the electricity consumption watts and/or the electricity consumption rates of various electrical appliances, and the user characteristic data is, for example, but not limited to a user age, a residential district, a family composition, and/or an electricity consumption habit. Specifically, the apparatus 1 for analyzing the electrical load provided by the present disclosure receives the household electricity consumption data and the household characteristic data of the user from the client device 2, selects one of the plurality of electricity consumption analysis models according to the household environment data of the user, generates the electricity consumption tracking list of the estimated electricity consumption statuses of various electrical appliances of the user via the electricity consumption analysis model according to the household electricity consumption data and the household environment data of the user, and transmits the electricity consumption tracking list to the client device 2. According to the electricity consumption tracking list received by the client device 2, the user may recognize and detect load statuses of various electrical appliances at home and adjust electricity consumption behaviors of various electrical appliances at home according to the load statuses. In an embodiment, the client device 2 may include, but is not limited to, an electricity meter, a gateway, and/or an operational device used by the user, such as a desktop computer, a laptop, and/or a smart phone, but not limited thereto. In an embodiment, the apparatus 1 for analyzing the electrical load may receive the household electricity consumption data of the user from the electricity meter and receive the household characteristic data of the user from the operational device used by the user.

Referring to FIG. 2, it is a schematic diagram of an apparatus 20 for modeling an electrical load provided by an embodiment of the present disclosure, which may be used for realizing the apparatus 10 for modeling the electrical load in FIG. 1. The apparatus 20 for modeling the electrical load provided by the present disclosure may include a receiving module 201, a processing module 202 that may be coupled to the receiving module 201, a non-volatile computer readable recording medium 203 that may be coupled to the processing module 202, and a storage module 204 that may be coupled to the processing module 202, and is configured to build a plurality of electricity consumption analysis models according to household electricity consumption data, user characteristic data, and household environment data of a user, where the household electricity consumption data is, for example, but not limited to the total circuit electricity consumption, and the electricity consumption watts and/or the electricity consumption rates of various electrical appliances, the user characteristic data is, for example, but not limited to a user age, a residential district, a family composition, and/or an electricity consumption habit, and the household environment data is, for example, but not limited to temperature and/or humidity. In an embodiment, the user characteristic data may be obtained from the user through a questionnaire (for example, the user fills in the questionnaire), and the user characteristic data obtained from the user may be stored in the apparatus 20 for modeling the electrical load (for example, the storage module 204).

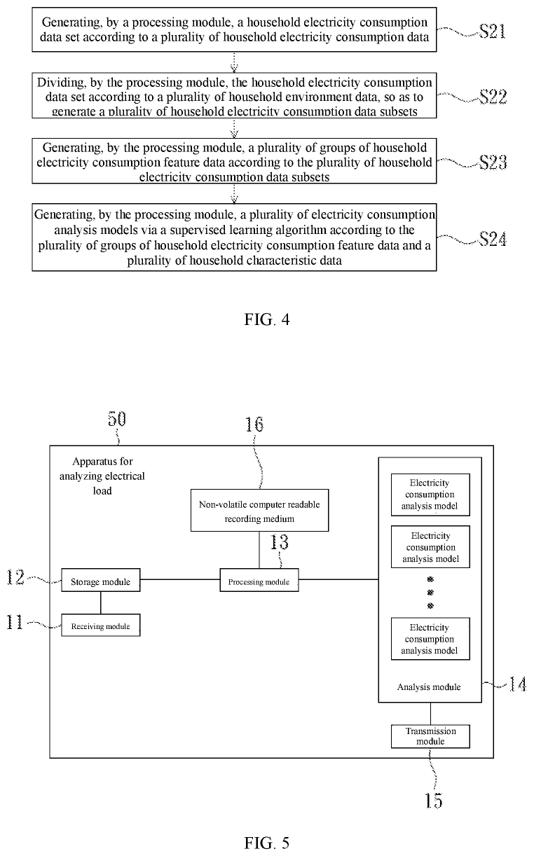

Referring to FIG. 3, it is a modeling flowchart of an apparatus for modeling an electrical load provided by an embodiment of the present disclosure, which may be used for the apparatus 20 for modeling the electrical load in FIG. 2. When the apparatus 20 for modeling the electrical load executes a flow 30 for modeling an electrical load, stored in the non-volatile computer readable recording medium 203, it may generate a plurality of electricity consumption analysis models according to a plurality of (e.g., pieces of) household electricity consumption data and a plurality of (e.g., pieces of) household characteristic data of a plurality of users. The modeling flow 30 includes the following steps: Step S1: receiving, by the receiving module 201, a plurality of (e.g., pieces of) household electricity consumption data and a plurality of (e.g., pieces of) household characteristic data of a plurality of users from a plurality of client devices 2. Step S2: generating, by the processing module 202, a plurality of electricity consumption analysis models according to the plurality of (e.g., pieces of) household electricity consumption data and the plurality of (e.g., pieces of) household characteristic data of the plurality of users, where Step S21, Step S22, Step S23, and Step S24 in the Step S2 of generating a plurality of electricity consumption analysis models will be illustrated in FIG. 4, and are not described first here. Step S3: (for example, cyclically) adjusting, by the processing module 202, parameters of the electricity consumption analysis models to influence the household electricity consumption feature data in the Step S23, and verifying the electricity consumption analysis models to optimize the accuracy of the electricity consumption analysis models. For example, when the accuracy of the electricity consumption analysis models is insufficient (such as below a preset threshold), the parameters of the electricity consumption analysis models may be adjusted, or other feature data may be added (such as for extraction or screening) to improve the accuracy of the electricity consumption analysis models. In conclusion, the apparatus 20 for modeling the electrical load generates the plurality of electricity consumption analysis models according to the household electricity consumption data, the user characteristic data, and the household environment data of the plurality of users, which will enable the apparatus 1 for analyzing the electrical load to accurately estimate the electricity consumption watts and/or the electricity consumption rates of various electrical appliances on that day.

Referring to FIG. 4, it is a flowchart of generating a plurality of electricity consumption analysis models provided by an embodiment of the present disclosure, which may be used for the apparatus 20 for modeling the electrical load in FIG. 2 and the Step S2 in FIG. 3. Step S21: generating, by the processing module 202, a household electricity consumption data set according to a plurality of (e.g., pieces of) household electricity consumption data. In detail, in an embodiment, when there is a missing value in the household electricity consumption data (for example, there is no electricity consumption data or the electricity consumption data is not received), the processing module 202 may supplement the missing value in the household electricity consumption data (for example, according to the electricity consumption data in the same time period on other days in that month and/or according to interpolation) to generate the household electricity consumption data set. When the missing value in the household electricity consumption data is supplemented and there is still a missing value in the total circuit electricity consumption, the total circuit electricity consumption stilling having the missing value needs to be deleted. In another embodiment, when a sampling format (such as a frequency) of the household electricity consumption data is different from a sampling format of the electricity consumption analysis models, the processing module 202 may re-sample the household electricity consumption data according to the sampling format of the plurality of electricity consumption analysis models to generate the household electricity consumption data set. For example, when the sampling format of the household electricity consumption data is different from the sampling format of the electricity consumption analysis models which is 1/900 Hz, the household electricity consumption data is re-sampled to be in the sampling format of 1/900 Hz. The sampling format of the household electricity consumption data may be a sampling format of a low frequency, such as less than 1/900 Hz or every 15 minutes, but not limited thereto. In another embodiment, when there is the missing value in the household electricity consumption data with different sampling format from the electricity consumption analysis models, the processing module 202 may supplement the missing value in the household electricity consumption data (for example, according to the electricity consumption data in the same time period on other days in that month and/or according to the interpolation) and re-sample the household electricity consumption data according to the sampling format of the plurality of electricity consumption analysis models to generate the household electricity consumption data set.

Step S22: dividing, by the processing module 202, the household electricity consumption data set according to a plurality of (e.g., pieces of) household environment data, so as to generate a plurality of household electricity consumption data subsets. In detail, the plurality of (e.g., pieces of) household environment data may be obtained from climate data on an open government platform and are analyzed and calculated to set a climate condition such as temperature and/or humidity. Then, the processing module 202 combines the household environment data and the household electricity consumption data set on the basis of a date (for example, combines the household environment data and the household electricity consumption data set on the same date), and generates the plurality of household electricity consumption data subsets by dividing the combined data by the household environment data (such as temperature).

Step S23: generating, by the processing module 202, a plurality of groups of household electricity consumption feature data according to the plurality of household electricity consumption data subsets. In detail, the processing module 202 counts one of the plurality of household electricity consumption data subsets according to a plurality of statistical feature factors to generate the plurality of groups of household electricity consumption feature data, where the processing module 202 obtains different statistical feature factors of each data set via (e.g., by means of) a statistical formula or signal processing, and converts wave type data in hour into lower-dimension household electricity consumption feature data, and the plurality of statistical feature factors include but are not limited to a mean, a standard deviation, a minimum value, a maximum value, a 5th percentile, a 95th percentile, a root mean square, a peak to peak factor, a peak factor, a skewness coefficient, a peak coefficient, a shape factor, and/or a cycle factor.

Step S24: generating, by the processing module 202, a plurality of electricity consumption analysis models via (e.g., by means of) a supervised learning algorithm according to the plurality of groups of household electricity consumption feature data and a plurality of (e.g., pieces of) household characteristic data, where the supervised learning algorithm may be a back propagation neural network (BPNN) algorithm, but is not limited thereto, and the back propagation neural network algorithm may be suitable for processed (extracted) feature data. In detail, the processing module 202 screens one of the plurality of groups of household electricity consumption feature data and the household characteristic data via (e.g., by means of) a feature selection algorithm to generate the plurality of groups of feature data. Then, the processing module 202 normalizes the plurality of groups of feature data to generate the plurality of electricity consumption analysis models via (e.g., by means of) the supervised learning algorithm. The feature selection algorithm used in this embodiment may be a least absolute shrinkage and selection operator (LASSO) algorithm, which may effectively screen features, but is not limited thereto, where the least absolute shrinkage and selection operator algorithm is a simple, fast, effective and accurate regression algorithm that may process a large amount of data and filter out noise. Those skilled in the art may select an appropriate feature screening method according to a calculation amount of the data, so the present disclosure does not limit the type of the feature selection algorithm. In addition, those skilled in the art may also select an appropriate neural network algorithm according to a calculation amount of the feature data, so the present disclosure does not limit the type of the neural network.

Referring to FIG. 5, it is a system block diagram of an apparatus 50 for analyzing an electrical load provided by an embodiment of the present disclosure, which may be used for realizing the apparatus 1 for analyzing the electrical load in FIG. 1. The apparatus 50 for analyzing the electrical load in the present disclosure includes a receiving module 11, a storage module 12 that may be coupled to the receiving module 11, a processing module 13 that may be coupled to the storage module 12, an analysis module 14 that may be coupled to the processing module 13, a transmission module 15 that may be coupled to the analysis module 14, and a non-volatile computer readable recording medium 16 that may be coupled to the processing module 13, where the apparatus 50 for analyzing the electrical load in the present disclosure executes a method for analyzing a household electrical load, stored in the non-volatile computer readable recording medium 16, so as to generate an electricity consumption tracking list of estimated electricity consumption statuses of various electrical appliances of a user via a plurality of electricity consumption analysis models according to household electricity consumption data and household environment data of the user. The electricity consumption tracking list may include but is not limited to the electricity consumption of various electrical appliances and its sequence, and adjustment suggestions and/or scheduling strategies for various (or specific) electrical appliances are provided to the user, such that the user can recognize and detect load statuses of various electrical appliances at home and adjust electricity consumption behaviors of various electrical appliances at home according to the load statuses. The household electricity consumption data is, for example, but not limited to the total circuit electricity consumption, the household environment data is, for example, but not limited to temperature and/or humidity, and various electrical appliances are, for example, but not limited to an air conditioner, a refrigerator, a washing machine, a television, and/or a water dispenser.

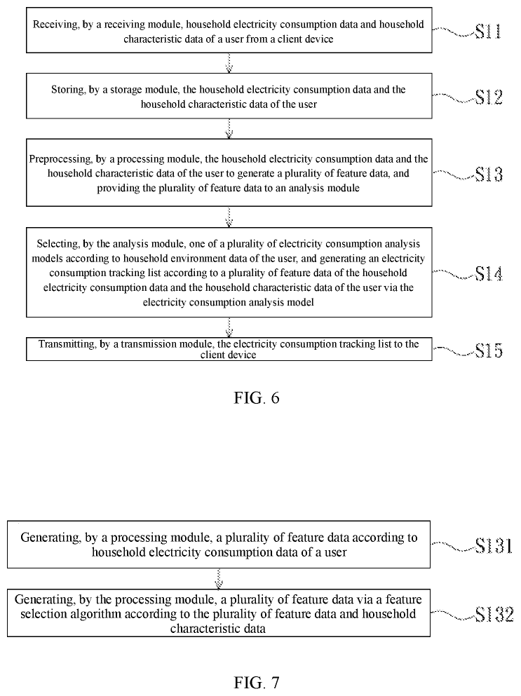

Referring to FIG. 6, it is a flowchart of a method for analyzing a household electrical load provided by an embodiment of the present disclosure, which may be used for the apparatus 50 for analyzing the electrical load in FIG. 5. The method for analyzing the household electrical load provided by the present disclosure includes the following steps: Step S11: receiving, by a receiving module 11, household electricity consumption data and household characteristic data of a user from a client device 2. Step S12: storing, by a storage module 12, the household electricity consumption data and the household characteristic data of the user. Step S13: preprocessing, by a processing module 13, the household electricity consumption data and the household characteristic data of the user to generate a plurality of (e.g., pieces of) feature data, and providing the plurality of (e.g., pieces of) feature data to an analysis module 14. Step S14: selecting, by the analysis module 14, one of a plurality of electricity consumption analysis models according to household environment data of the user, and generating an electricity consumption tracking list according to a plurality of (e.g., pieces of) feature data of the household electricity consumption data and the household characteristic data of the user via the electricity consumption analysis model. Step S15: transmitting, by a transmission module 15, the electricity consumption tracking list to the client device 2.

Referring to FIG. 7, it is a flowchart of preprocessing household electricity consumption data to generate feature data provided by an embodiment of the present disclosure. The Step S13 may further include: Step S131: generating (for example, extracting), by the processing module 13, the plurality of (e.g., pieces of) feature data according to the household electricity consumption data of the user, where the Step S131 has the same data processing process as the Steps S21 to S23, so it will not be repeated. Step S132: generating (for example, screening out), by the processing module 13, a plurality of (e.g., pieces of) feature data via (e.g., by means of) a feature selection algorithm according to the plurality of (e.g., pieces of) feature data and household characteristic data, where the processing module 13 screens the plurality of (e.g., pieces of) feature data and the household feature data via (e.g., by means of) the LASSO algorithm to generate the plurality of (e.g., pieces of) feature data.

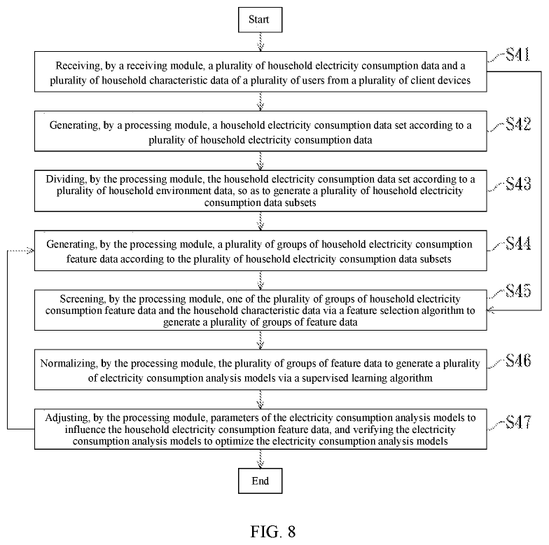

Referring to FIG. 8, it is a modeling flowchart of an apparatus for modeling an electrical load provided by another embodiment of the present disclosure, which may be used for the apparatus 20 for modeling the electrical load in FIG. 2. When the apparatus 20 for modeling the electrical load executes a flow 40 for modeling an electrical load, stored in the non-volatile computer readable recording medium 203, it may generate a plurality of electricity consumption analysis models according to a plurality of (e.g., pieces of) household electricity consumption data and a plurality of (e.g., pieces of) household characteristic data of a plurality of users. The modeling flow 40 includes the following steps: Step S41: receiving, by the receiving module 201, a plurality of (e.g., pieces of) household electricity consumption data and a plurality of (e.g., pieces of) household characteristic data of a plurality of users from a plurality of client devices 2, where the Step S41 has the same data processing process as the Step S1, so it will not be repeated. Step S42: generating, by the processing module 202, a household electricity consumption data set according to a plurality of (e.g., pieces of) household electricity consumption data, where the Step S42 has the same data processing process as the Step S21, so it will not be repeated. Step S43: dividing, by the processing module 202, the household electricity consumption data set according to a plurality of (e.g., pieces of) household environment data, so as to generate a plurality of household electricity consumption data subsets, where the Step S43 has the same data processing process as the Step S22, so it will not be repeated. Step S44: generating, by the processing module 202, a plurality of groups of household electricity consumption feature data according to the plurality of household electricity consumption data subsets, where the Step S44 has the same data processing process as the Step S23, so it will not be repeated. Step S45: screening, by the processing module 202, one of the plurality of groups of household electricity consumption feature data and the household characteristic data via (e.g., by means of) a feature selection algorithm to generate a plurality of groups of feature data, where the Step S45 has the data processing process as same as part of the data processing process in the Step S24, so it will not be repeated. Step S46: normalizing, by the processing module 202, the plurality of groups of feature data to generate a plurality of electricity consumption analysis models via (e.g., by means of) a supervised learning algorithm, where the Step S46 has the data processing process as same as part of the data processing process in the Step S24, so it will not be repeated. Step S47: (for example, cyclically) adjusting, by the processing module 202, parameters of the electricity consumption analysis models to influence the household electricity consumption feature data in the Step S44, and verifying the electricity consumption analysis models to optimize the accuracy of the electricity consumption analysis models, where the Step S47 has the same data processing process as the Step S3, so it will not be repeated.

In addition, it should be noted that in the above embodiment, the modules, the non-volatile computer readable recording medium, etc. included in the apparatuses 1 and 50 for analyzing the electric load and the apparatuses 10 and 20 for modeling the electrical load are implemented by hardware (such as a circuit), software (such as instructions or program codes), firmware (such as a combination of software and hardware), or a combination thereof. The above processing modules 13 and 202 may be implemented by a microprocessor, a controller, a central processing unit (CPU), or a combination thereof, the above receiving modules 11 and 201 and the above transmission module 15 may be implemented by a wireless or wired communication device, the above storage modules 12 and 204 may be implemented by a memory, a hard disk, or a combination thereof, and the above analysis module 14 may be implemented by a server.

In an embodiment, the processing module 13 in the apparatus 50 for analyzing the electric load and the processing module 202 in the apparatus 20 for modeling the electric load may be the same processing module. In an embodiment, the receiving module 11 in the apparatus 50 for analyzing the electric load and the receiving module 201 in the apparatus 20 for modeling the electric load may be the same receiving module. In an embodiment, the non-volatile computer readable recording medium 16 in the apparatus 50 for analyzing the electric load and the non-volatile computer readable recording medium 203 in the apparatus 20 for modeling the electric load may be the same non-volatile computer readable recording medium. In an embodiment, the storage module 12 in the apparatus 50 for analyzing the electric load and the storage module 204 in the apparatus 20 for modeling the electric load may be the same storage module. In an embodiment, various modules in the apparatus 50 for analyzing the electric load may be integrated into one or more modules for implementation. In an embodiment, various modules in the apparatus 20 for modeling the electric load may be integrated into one or more modules for implementation.

In conclusion, the present disclosure collects the household electricity consumption data, the user characteristic data and the household environment data of the user, and provides the data to the electricity consumption analysis models for analyzing electricity consumption histories of various electrical appliances at home. The present disclosure provides the client device with the electricity consumption tracking list of various electrical appliances at home, such that the user can recognize and detect load statuses of various electrical appliances at home. Meanwhile, the present disclosure gives customized electricity consumption diagnoses and electricity consumption adjustment suggestions and strategies such that the user can adjust electricity consumption behaviors of various electrical appliances at home, thereby providing different thinkings and innovations for energy efficiency and demand response.

1. An apparatus for analyzing an electrical load, comprising:
a receiving module configured to receive first household electricity consumption data and first household characteristic data of a first user from a client device;
an analysis module coupled to the receiving module and configured to select an electricity consumption analysis model of a plurality of electricity consumption analysis models according to first household environment data of the first user, and to generate an electricity consumption tracking list according to a plurality of first feature data of the first household electricity consumption data and the first household characteristic data via the electricity consumption analysis model; and
a transmission module coupled to the analysis module and configured to transmit the electricity consumption tracking list to the client device.

2. The apparatus for analyzing an electrical load according to claim 1, further comprising:
a storage module coupled to the receiving module and configured to store the first household electricity consumption data and the first household characteristic data.

3. The apparatus for analyzing an electrical load according to claim 1, further comprising:
a processing module coupled to the receiving module and configured to preprocess the first household electricity consumption data and the first household characteristic data to generate the plurality of first feature data, and to provide the plurality of first feature data to the analysis module.

4. The apparatus for analyzing an electrical load according to claim 3, wherein preprocessing the first household electricity consumption data and the first household characteristic data to generate the plurality of first feature data further comprises:
generating a plurality of second feature data according to the first household electricity consumption data; and
generating the plurality of first feature data according to the plurality of second feature data and the first household characteristic data.

5. The apparatus for analyzing an electrical load according to claim 1, wherein the plurality of electricity consumption analysis models are generated according to a plurality of second household electricity consumption data and a plurality of second household characteristic data of a plurality of second users.

6. The apparatus for analyzing an electrical load according to claim 5, wherein generating the plurality of electricity consumption analysis models according to the plurality of second household electricity consumption data and the plurality of second household characteristic data of the plurality of second users further comprises:
generating a household electricity consumption data set according to the plurality of second household electricity consumption data;
dividing the household electricity consumption data set according to a plurality of second household environment data, so as to generate a plurality of household electricity consumption data subsets;
generating a plurality of groups of first household electricity consumption feature data according to the plurality of household electricity consumption data subsets;
generating a plurality of groups of second household electricity consumption feature data via a feature selection algorithm according to the plurality of groups of first household electricity consumption feature data and the plurality of second household characteristic data; and
generating the plurality of electricity consumption analysis models via a supervised learning algorithm according to the plurality of groups of second household electricity consumption feature data.

7. The apparatus for analyzing an electrical load according to claim 6, wherein the feature selection algorithm comprises a least absolute shrinkage and selection operator (LASSO) algorithm.

8. The apparatus for analyzing an electrical load according to claim 6, wherein the supervised learning algorithm comprises a back propagation neural network (BPNN) algorithm.

9. The apparatus for analyzing an electrical load according to claim 1, wherein the plurality of electricity consumption analysis models are generated by the analysis module.

10. The apparatus for analyzing an electrical load according to claim 1, wherein the plurality of electricity consumption analysis models are generated by an apparatus for modeling an electrical load.

11. A method for analyzing an electrical load, the method being used for an apparatus for analyzing an electrical load, the method comprising:
receiving first household electricity consumption data and first household characteristic data of a first user from a client device;
selecting an electricity consumption analysis model of a plurality of electricity consumption analysis models according to first household environment data of the first user, and to generate an electricity consumption tracking list according to a plurality of first feature data of the first household electricity consumption data and the first household characteristic data via the electricity consumption analysis model; and
transmitting the electricity consumption tracking list to the client device.

12. The method for analyzing an electrical load according to claim 11, further comprising:
storing the first household electricity consumption data and the first household characteristic data.

13. The method for analyzing an electrical load according to claim 11, further comprising:
preprocessing the first household electricity consumption data and the first household characteristic data to generate the plurality of first feature data, and providing the plurality of first feature data to the analysis module.

14. The method for analyzing an electrical load according to claim 13, wherein preprocessing the first household electricity consumption data and the first household characteristic data to generate the plurality of first feature data further comprises:
generating a plurality of second feature data according to the first household electricity consumption data; and
generating the plurality of first feature data via a feature selection algorithm according to the plurality of second feature data and the first household characteristic data.

15. The method for analyzing an electrical load according to claim 11, wherein the plurality of electricity consumption analysis models are generated according to a plurality of second household electricity consumption data and a plurality of second household characteristic data of a plurality of second users.

16. The method for analyzing an electrical load according to claim 15, wherein generating the plurality of electricity consumption analysis models according to the plurality of second household electricity consumption data and the plurality of second household characteristic data of the plurality of second users further comprises:
generating a household electricity consumption data set according to the plurality of second household electricity consumption data;
dividing the household electricity consumption data set according to a plurality of second household environment data, so as to generate a plurality of household electricity consumption data subsets;
generating a plurality of groups of first household electricity consumption feature data according to the plurality of household electricity consumption data subsets;
generating a plurality of groups of second household electricity consumption feature data via a feature selection algorithm according to the plurality of groups of first household electricity consumption feature data and the plurality of second household characteristic data; and
generating the plurality of electricity consumption analysis models via a supervised learning algorithm according to the plurality of groups of second household electricity consumption feature data.

17. The method for analyzing an electrical load according to claim 16, wherein the feature selection algorithm comprises an LASSO algorithm.

18. The method for analyzing an electrical load according to claim 16, wherein the supervised learning algorithm comprises a BPNN algorithm.

19. An apparatus for modeling an electrical load, comprising:
a receiving module configured to receive a plurality of household electricity consumption data and a plurality of household characteristic data of a plurality of users from a plurality of client devices; and
a processing module coupled to the receiving module and configured to generate a plurality of electricity consumption analysis models according to the plurality of household electricity consumption data and the plurality of household characteristic data of the plurality of users.

20. The apparatus for modeling an electrical load according to claim 19, wherein the processing module generating the plurality of electricity consumption analysis models according to the plurality of household electricity consumption data and the plurality of household characteristic data of the plurality of users further comprises:
generating a household electricity consumption data set according to the plurality of household electricity consumption data;
dividing the household electricity consumption data set according to a plurality of household environment data, so as to generate a plurality of household electricity consumption data subsets;
generating a plurality of groups of first household electricity consumption feature data according to the plurality of household electricity consumption data subsets;
generating a plurality of groups of second household electricity consumption feature data via a feature selection algorithm according to the plurality of groups of first household electricity consumption feature data and the plurality of household characteristic data; and
generating the plurality of electricity consumption analysis models via a supervised learning algorithm according to the plurality of groups of second household electricity consumption feature data.

21. The apparatus for analyzing an electrical load according to claim 20, wherein the feature selection algorithm comprises an LASSO algorithm.

22. The apparatus for analyzing an electrical load according to claim 20, wherein the supervised learning algorithm comprises a BPNN algorithm.
